(19) United States
(12) Patent Application Publication
(10) Pub. No.: US 2012/0025065 A1
(43) Pub. Date: Feb. 2, 2012

(54) ELECTRONIC DEVICE HAVING SOLAR ENERGY COLLECTING MODULE

(75) Inventors: PING-YANG CHUANG, Tu-Cheng (TW); YING-CHUAN YU, Tu-Cheng (TW)

(73) Assignee: HON HAI PRECISION INDUSTRY CO., LTD., Tu-Cheng (TW)

(21) Appl. No.: 12/977,072

(22) Filed: Dec. 23, 2010

(30) Foreign Application Priority Data
Jul. 29, 2010 (TW) 99125201

(51) Int. Cl. H01J 3/14; H05K 7/00

(52) U.S. Cl. 250/216; 361/679.01

(57) ABSTRACT

A electronic device includes a display and a housing to house the display. A solar energy collector is arranged on a internal sidewall of the housing, and converts solar energy into electricity. A beam splitter is arranged on and covers the display, and reflecting incident light to the solar energy collector.

### RELATED APPLICATIONS

This application is related to a U.S. patent application with an Attorney Docket Number of US33150 and a title of ELECTRONIC DEVICE HAVING SOLAR ENERGY MODULE, which has the same assignee as the current application and was concurrently filed.

### BACKGROUND

1. Technical Field

The present disclosure relates to electronic devices having solar energy collectors and, particularly, to an electronic device having light path changing module to allow ambient light beam to be projected onto the solar energy collector.

2. Description of Related Art

Energy consumption of portable consumer electronic products has always been a concern. There exists portable consumer electronic products equipped with a solar energy collector to collect solar energy. However, it needs to set an opening in the housing of the electronic product to allow ambient light to pass through, which may affect the appearance of the electronic product.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic cross-sectional view of a portable electronic device in accordance with one embodiment.

FIG. 2 is a schematic cross-sectional view of a portable electronic device in accordance with a second embodiment.

FIG. 3 is a schematic cross-sectional view of a portable electronic device in accordance with a third embodiment.

FIG. 4 shows a light path when ambient light projects onto the portable electronic device of FIG. 3.

### DETAILED DESCRIPTION

Embodiments of the present disclosure will now be described in detail below, with reference to the accompanying drawings.

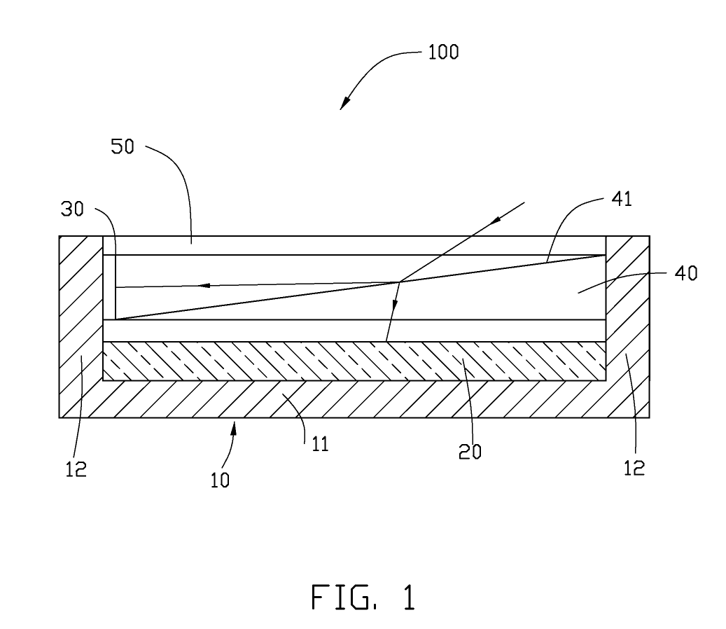

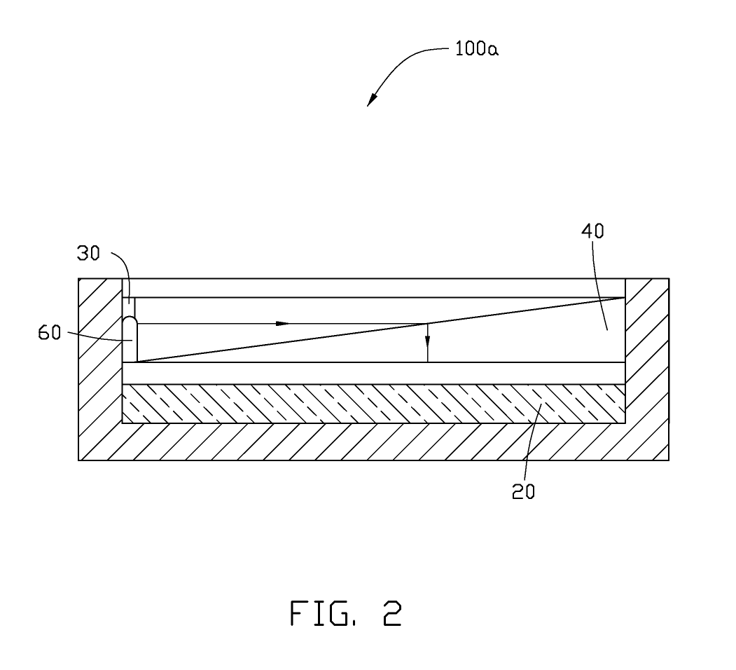

Referring to FIGS. 1 and 2, an electronic device 100 includes a housing 10 and a display 20. The housing 10 includes a bottom 11 and two opposite sidewalls 12. The display 20 is received in a space defined by the bottom 11 and the sidewalls 12. The electronic device 100 further includes a solar energy collector 30 and a beam splitter 40. The solar energy collector 30 is arranged on one sidewall 12 and converts solar energy into electricity.

The beam splitter 40 is arranged above and covers the display 20. In the embodiment, the beam splitter 40 is made of glass and is wedge-shaped. The beam splitter 40 includes a sloping surface 41 that is covered by a coating, allowing a portion of light beams projecting on the sloping surface 41 to be reflected, and allowing the rest of the light beams to pass through the beam splitter 40 and project onto the display 20. The reflected light projects onto the solar energy collector 30. The electricity produced by the solar energy collector 30 powers the electronic device 100.

In the embodiment, the display 20 can be a reflective type display, such as a microcapsule type electronic paper display. The display 20 can use light passing through the beam splitter 40 as a light source. In the embodiment, the electronic device 100 further includes a protection plate arranged between the sidewalls 12 of the housing, to protect the beam splitter 40 from being scratched.

Referring to FIG. 2, in an alternative embodiment, an electronic device 100a is disclosed. The difference between the electronic devices 100 and 100a is that the electronic device 100a further includes a lighting module 60. The lighting module 60 is arranged on the sidewall 12 where the solar energy collector 30 is arranged. When the ambient light is weak, the lighting module 60 can be turned on to emit light, a portion of which can pass through the beam splitter 40 and project onto display 20. The electronic device 100a can still display information in such circumstance. In the embodiment, the lighting module 60 includes a number of light emitting diodes (LEDs).

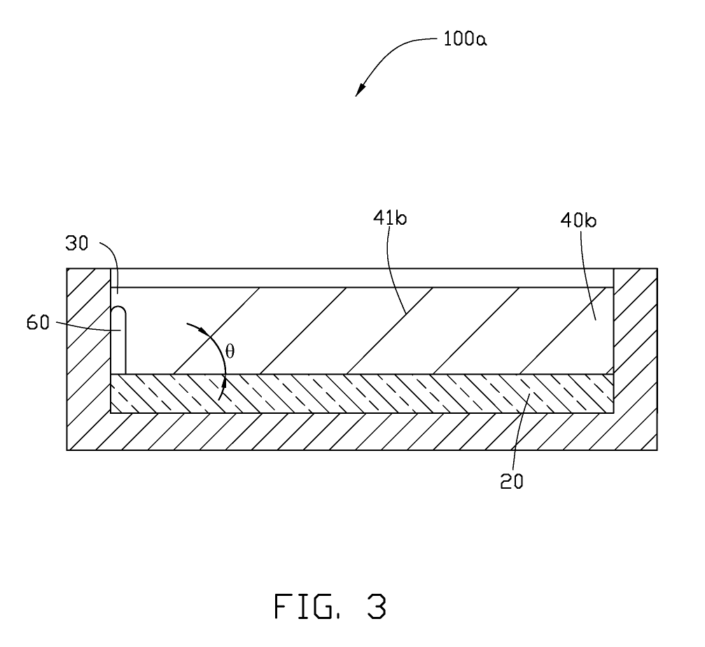

Referring to FIG. 3, in another alternative embodiment, an electronic device 100b is disclosed. The difference between the electronic devices 100b and 100a is that the electronic device 100b includes a different beam splitter 40b. The beam splitter 40b includes a number of parallel sloping surfaces 41b. Each sloping surface 41b is covered by a coating, allowing a portion of light beams projecting on the sloping surface 41b to be reflected, and allowing the rest of the light beams to pass through the beam splitter 40b and project onto the display 20. In the embodiment, each sloping surface 41b has an inclined angle of about 45 degrees relative to the display 20.

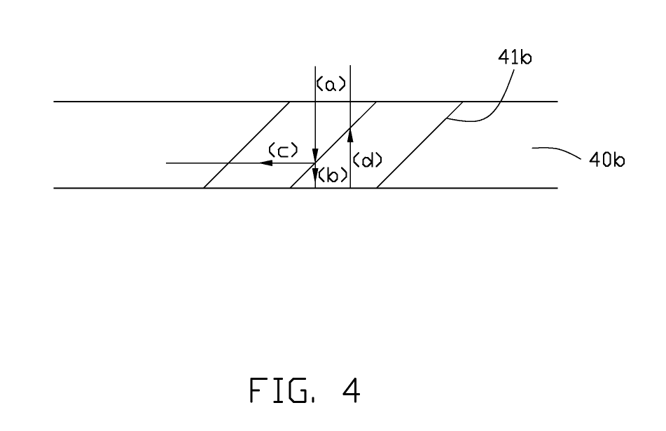

Referring to FIG. 4, when an ambient light beam A projects on the beam splitter 40b, a portion of the light beam A (referred to as light beam B) passes through the beam splitter 40b and projects on the display 20. The rest of the light beam A (light beam C) is reflected and projects onto the solar energy collecting module 30. The light beam D that is reflected by the display 20 passes through the beam splitter 40b and is visible by viewers.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a display;
a housing configured to house the display;
a solar energy collecting module arranged on an internal sidewall of the housing, and configured for converting light into electricity; and
a beam splitter arranged on and covering the display, and configured for reflecting incident light to the solar energy collecting module.

2. The electronic device according to claim 1, wherein the display is a reflective type display.

3. The electronic device according to claim 1, further comprising a protection cover arranged over the beam splitter.

4. The electronic device according to claim 1, wherein the beam splitter comprises a plurality of sloping reflective surfaces that are parallel to each other, allowing a portion of the incident light to be reflected, and allowing the rest of the incident light to pass through.

5. The electronic device according to claim 4, wherein each of the plurality of slopping reflective surface has an angle of about 45 degrees relative to a display surface of the display.

6. The electronic device according to claim 1, wherein the beam splitter comprises a sloping reflective surface, allowing a portion of the incident light to be reflected, and allowing the rest of the incident light to pass through.

7. An electronic reader comprising:
a display;
a housing configured to house the display;
a solar energy collecting module arranged on an internal sidewall of the housing, and configured for converting light into electricity;
a lighting module arranged on the internal sidewall; and
a beam splitter arranged on and covering the display, and configured for reflecting incident light to the solar energy collecting module, wherein light from the lighting module is able to pass through beam splitter

8. The electronic reader according to claim 7, wherein the display is a reflective type display.

9. The electronic reader according to claim 7, further comprising a protection cover arranged over the beam splitter.

10. The electronic reader according to claim 7, wherein the lighting module comprises a plurality of light emitting diodes.

11. The electronic reader according to claim 7, wherein the beam splitter comprises a plurality of sloping reflective surface that are parallel to each other, allowing a portion of the incident light to be reflected, and allowing the rest of the incident light to pass through.

12. The electronic reader according to claim 11, wherein each of the plurality of slopping reflective surface has an angle of about 45 degrees relative to a display surface of the display.

13. The electronic reader according to claim 11, wherein the beam splitter comprises a sloping reflective surface, allowing a portion of the incident light to be reflected, and allowing the rest of the incident light to pass through.
